(19) United States
(12) Patent Application Publication
(10) Pub. No.: US 2018/0122976 A1
(43) Pub. Date: May 3, 2018

(54) Solar Cell Module

(71) Applicant: Nexiot AG, Zurich (CH)

(72) Inventors: Christoph Wartmann, Mannedorf (CH); Sandro Gähler, Zurich (CH)

(21) Appl. No.: 15/796,238

(22) Filed: Oct. 27, 2017

(30) Foreign Application Priority Data
Oct. 28, 2016 (EP) 16196276.6

(51) Int. Cl. H01L 31/05; H01L 31/048

(52) U.S. Cl. CPC H01L 31/0508; H01L 31/048

(57) ABSTRACT

A solar cell module has a rear housing to accommodate a photovoltaic cell module attached to the rear housing and comprising an array of photovoltaic cells arranged opposite to the rear housing wall. The solar cell module further comprises a grid comprising webs, wherein the grid is attached on the upper surface of the photovoltaic cell module and partly on the surrounding rear housing, wherein the webs define window openings essentially provided in front of the photovoltaic cells thus that the webs do not shadow the photovoltaic cells.

### CROSS-REFERENCE TO RELATED APPLICATION

This application claims priority to European Patent Application No. 16196276.6 filed Oct. 28, 2016, the disclosure of which is hereby incorporated in its entirety by reference.

### BACKGROUND OF THE INVENTION

### Field of the Invention

The present invention relates to a solar cell module having a rear housing to accommodate a photovoltaic cell module attached to the rear housing, wherein the photovoltaic cell module comprises an array of photovoltaic cells arranged opposite to the rear housing wall as well as a method producing such a solar cell module.

### Description of Related Art

WO 2016/010881 A2 relates to a portable light having a battery, wherein in [0087] it is mentioned that such a battery can also be a solar cell, fuel cells, super capacitors, solar cells, and the like. At the same time the prior art mentions the standard IEC 60079 which are for devices that are to be used in hazardous locations and/or environments.

WO 2010/147660 A2 discloses an intrinsically safe video inspection system using a photovoltaic cell 430. The device is considered to be usable under IEC 60079 conditions.

US 2001/029976 A1 describes a photovoltaic cell, wherein, when the substrate is opaque, the upper electrode layer is located on the light incident side and is able to transmit light, that is, is a transparent electrode, wherein a transparency of 85% and a low sheet resistance value is mentioned.

### SUMMARY OF THE INVENTION

It is an object of the invention to provide a solar cell module being intrinsically safe in the sense of the norm IEC 60079 or similar standards for intrinsic safety. It is a further object of the invention to provide a method of making large solar cell modules complying with regulations for intrinsic safety in explosive atmospheres.

In accordance with one example of the invention, solar cell module has a rear housing to accommodate a photovoltaic cell module attached to the rear housing and comprising an array of photovoltaic cells arranged opposite to the rear housing wall. The solar cell module further comprises a grid comprising webs, wherein the grid is attached on the upper surface of the photovoltaic cell module and partly on the surrounding rear housing, wherein the webs define window openings essentially provided in front of the photovoltaic cells thus that the webs do not shadow the photovoltaic cells.

The grid of the solar cell module is electrically conductive, especially made of a punched metal sheet. The grid can be attached to the photovoltaic cell module and the rear housing with an adhesive. Such an adhesive is preferredly a non-conductive adhesive but it can also be a conductive adhesive.

The solar cell module can also have a grid being printed as a screen print on the upper surface of the photovoltaic cell module and partly on the surrounding rear housing. It is then preferred to build the solar cell module within a metallic casing contacting the screen printed grid at the surrounding rear housing building an encompassing Faraday cage.

The photovoltaic cell module can be attached in a recess of the rear housing with a volume adhesive. Then it can be achieved that the upper side of the rear housing and the upper side of the photovoltaic cell module are flush so that the grid forms—together with the rear housing—a sturdy case for the solar cell module.

A method producing a solar cell module with a grid comprises the steps of providing a rear housing, positioning a photovoltaic cell module in the rear housing, providing a conductive grid, applying an adhesive either on the back side of the conductive grid or on positions complementary to the grid on the photovoltaic cell module and on the rear housing, and attaching the grid on the photovoltaic cell module and on the rear housing.

Preferably the grid, e.g. as punched sheet, is pre-bent in the direction on the surface of the photovoltaic cell module to ensure a good contact on the photovoltaic cell module.

When the photovoltaic cell module is positioned in the rear housing, it is preferred to apply a volume adhesive in a recess in the rear housing, followed by positioning the photovoltaic cell module in this recess in a way that the upper surface of the photovoltaic cell module is flush with the upper surface of the rear housing, and hardening of the volume adhesive. Then application of the grid on this flush surface ensures a good contact of the grid over the photovoltaic cell module as well as on the surrounding housing.

In order to provide a complete Faraday cage for the solar cell module, it is possible to provide an additional housing comprising a conductive layer encompassing the rear housing as well as contacting the complete edge area of the grid. Of course, the additional housing does not need to have a conductive outer surface, it is sufficient that there is an internal conductive layer ending near the grid edges and closing the inner space in the sense of said Faraday cage.

Further embodiments of the invention are laid down in the dependent claims.

### BRIEF DESCRIPTION OF THE DRAWINGS

Preferred embodiments of the invention are described in the following with reference to the drawings, which are for the purpose of illustrating the present preferred embodiments of the invention and not for the purpose of limiting the same. In the drawings,

FIG. 1 shows a perspective view of a solar cell module according to an embodiment of the invention in a case; and

FIG. 2 shows a schematic cross section of the solar cell module according to FIG. 1.

### DESCRIPTION OF THE INVENTION

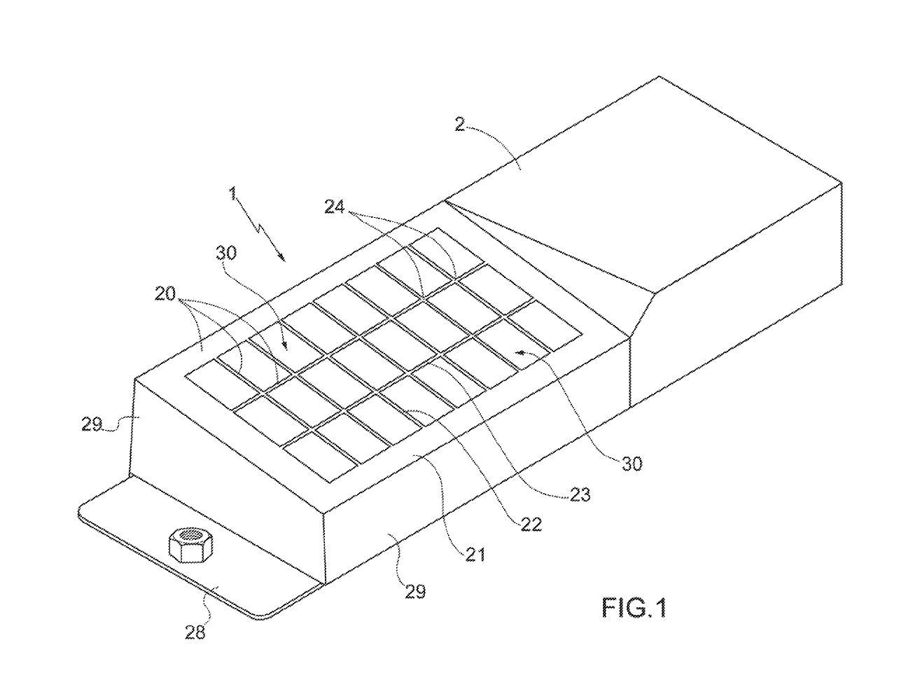

FIG. 1 shows a perspective view of a solar cell module 1 according to an embodiment of the invention in a case 2.

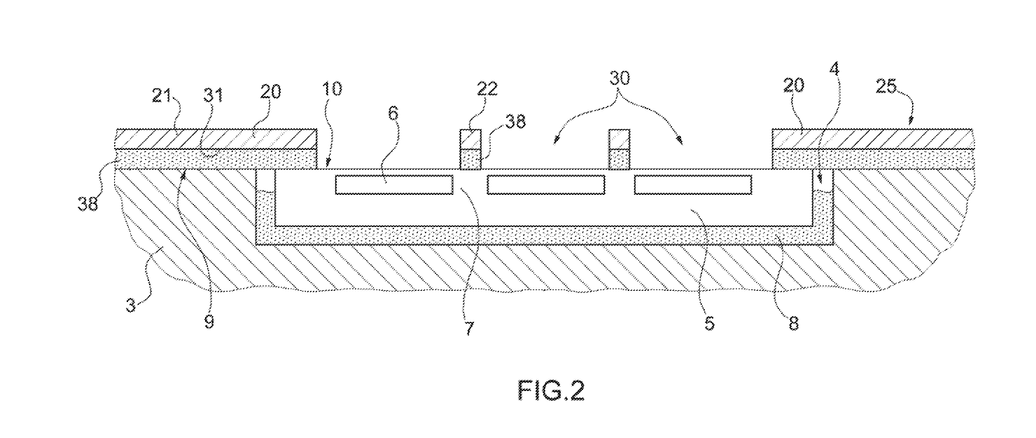

The solar cell module 1 is better shown in the schematic cross section of FIG. 2. The solar cell module 1 comprises a rear housing 3 which can be part of the case 2. The rear housing 3 comprises a recess 4, especially a rectangular recess to accommodate a photovoltaic cell module 5. A typical commercial photovoltaic cell module 5 comprises an array of single photovoltaic elements 6 embedded in a substrate 7 making up for the cuboid body of the photovoltaic cell module 5. The photovoltaic cell module 5 also comprises electrical connection lines (not shown) between the various elements in the substrate. The photovoltaic cell module 5 of the present invention does not comprise parts of control units of the photovoltaic cells 6 but it is possible to include such control units in the design. The rear housing 3 can comprise openings (not shown) for the passage of electrical connection lines of the photovoltaic cell module 5.

The photovoltaic cell module 5 is attached to the rear housing 3, preferably by an adhesive 8, which is preferredly filled into the recess 4 before accommodating the solar cell module 5. The adhesive 8 is a glue or volume adhesive to fill the space between the recess bottom and walls and the solar cell module back and side surfaces. It is possible but not necessarily preferred that the adhesive 8 does not fill the gap between the solar cell module 5 and the rear housing near the upper surface 9 of the rear housing 3. It is preferred that the upper surface 10 of the solar cell module 5 is more or less flush with the upper surface 9 of the rear housing 3.

The solar cell module 1 then further comprises a grid 20 having a circumferential side portion 21 and column webs 22 as well as crossing line webs 23. The column webs 22 and line webs 23 are connected at the crossing points 24, separating the grid surface into a plurality of windows 30. The border area 21 of the grid 20 is usually larger but is considered—according to the present invention to form part of the webs.

The grid 20 is electrically conductive. It is especially made of a metal. It is coated on the back side 31 with a further adhesive 38 used to attach said backside 31 to the upper surface 9 of the rear housing. Adhesive 38 can also be provided on the upper surface 9, but the alignment with the photovoltaic cells 6 is more complicated.

Coming back to FIG. 1, it is possible to provide a case-like grid element 20 having punched and folded side surfaces 29 and even a folded attachment flap 28, all made in one single piece. Then the Faraday cage effect is even more pronounced, since the windows 30 are the only openings to the environment, and they are sufficiently small without hindering the light to reach the active surface of the solar cell module 1.

The distances between the webs 21 and 22 of the grid 20 are chosen to be essentially in line and positioned at the portions of the photovoltaic cell module 5 which are not comprising photovoltaic cell elements 6 so that most or all of the active surfaces of the photovoltaic cell elements 6 are in front of the windows 30.

The photovoltaic cells 6 used in the embodiment shown have a size of approximately 12×20 millimeters which are provided in a distance of 3 millimeters one from the other in both directions (column and row). Each window has a dimension of 14×22 millimeters and the webs 21 and 22 have a width of 2 millimeters. Then the photovoltaic cells 6 are entirely exposed to any light falling through the windows 30.

Each window 30 has a surface of 308 mm². IEC 60079-0 (Explosive Atmospheres—Part 0: Equipment—General requirements) require a covering on a conductive material, if the surface area exceeds 500 mm². Coatings known from the prior art are not very transparent and would reduce the efficiency of the solar module 1 quite drastically. Therefore, providing a plurality of windows 30 separated with webs 21 and 22 and a border area 20, fulfils the requirements of the standard while maintaining a high efficiency of the solar module 1. Windows 30 can be up to 22 mm×22 mm, if a square area of the photovoltaic cell 6 is available to remain below said 500 mm².

As shown in FIG. 2, the grid 20 is partly attached with its webs 21, 22 on the upper surface 10 of the photovoltaic cell module 5 and partly on the rear housing 3. This provides a solar cell module 1 comprising a rear housing 3, a photovoltaic cell module 5 with embedded solar cells 6 covered by a grid 20 dividing the upper surface 10 of the photovoltaic cell module 5 (usually far larger than 500 mm²) into an array of smaller windows 30 with the photovoltaic cells 6 behind.

In order to secure the grid 20 on the upper surface 10 and on the upper surface 9 of the photovoltaic cell module 5 and rear housing 3, respectively, the adhesive 38 is applied in advance on the back side 31 of the grid 20 and a slight preload. The preload is related to the grid 20 being bent towards the middle of the photovoltaic cell surface pushing onto it and maintaining the pressure on the adhesive.

In an embodiment not shown in the drawings the solar cell module can also have a grid 20 being printed as a screen print on the upper surface 9 of the photovoltaic cell module 5 and partly on the surrounding rear housing 3. Then the webs 22 and 23 as well as the border area 21 is directly printed on the respective areas. The screen print of electrical conductive material of e.g. 100 micrometers thickness ensures the same function as the mechanical grid 20.

LIST OF REFERENCE SIGNS

| | |
|---|---|
| 1 | solar cell module |
| 2 | case |
| 3 | rear housing |
| 4 | gap |
| 5 | photovoltaic cell module |
| 6 | photovoltaic cell |
| 7 | substrate |
| 8 | volume adhesive |
| 9 | upper side of rear housing |
| 10 | upper side of photovoltaic |
| | cell module |
| 20 | grid |
| 21 | border area |
| 22 | column web |
| 23 | line web |
| 24 | crossing point |
| 25 | upper surface of grid |
| 28 | bottom attachment flap |
| 29 | side surface |
| 30 | window |
| 31 | underside of grid |
| 38 | adhesive |

1. A solar cell module comprising:
a photovoltaic cell module comprising an array of photovoltaic cells;
a rear housing to accommodate the photovoltaic cell module attached to the rear housing; and
an electrically conductive grid comprising webs,
wherein the array of photovoltaic cells is arranged opposite to a rear housing wall of the rear housing, wherein the electrically conductive grid is attached on an upper surface of the photovoltaic cell module and partly on a surrounding portion of the rear housing, and wherein the webs define window openings essentially provided in front of the array of photovoltaic cells.

2. The solar cell module according to claim 1, wherein the photovoltaic cell module is attached in a recess of the rear housing with a volume adhesive, wherein an upper side of the rear housing and an upper side of the photovoltaic cell module are flush.

3. The solar cell module according to claim 1, wherein each window opening defined by the webs has a window surface smaller than 500 mm².

4. The solar cell module according to claim 1, wherein the electrically conductive grid is made of a punched metal sheet.

5. The solar cell module according to claim 4, wherein the rear housing comprises a number of side walls and a back wall, wherein the metal sheet covers at least one of the side walls and back walls of the rear housing.

6. The solar cell module according to claim 4, wherein the electrically conductive grid is directly attached to the photovoltaic cell module and the rear housing with an adhesive.

7. The solar cell module according to claim 6, wherein the adhesive is a non-conductive adhesive.

8. The solar cell module according claim 1, wherein the electrically conductive grid is printed as a screen print of conductive material on the upper surface of the photovoltaic cell module and partly on the surrounding portion of the rear housing.

9. The solar cell module according to claim 8, wherein the electrically conductive grid is directly attached to the photovoltaic cell module and the rear housing with an adhesive.

10. The solar cell module according to claim 9, wherein the adhesive is a non-conductive adhesive.

11. A method of producing a solar cell module having a photovoltaic cell module and a rear housing comprising;
accommodating the photovoltaic cell module in the rear housing;
providing a number of photovoltaic cells in an array of photovoltaic cells;
arranging the array of photovoltaic cells opposite to a rear housing wall of the rear housing;
attaching the photovoltaic cell module in the rear housing;
providing an electrically conductive grid comprising webs on an upper surface of the photovoltaic cell module and partly on a surrounding portion of the rear housing, wherein the webs define window openings essentially provided in front of the array of photovoltaic cells;
applying an adhesive on one of a back side of the electrically conductive grid or on positions complementary to the electrically conductive grid on the photovoltaic cell module and on the rear housing, and
attaching the electrically conductive grid on the photovoltaic cell module and on the rear housing.

12. The method according to claim 11, wherein providing the electrically conductive grid comprises pre-bending the grid in a direction on an upper surface of the photovoltaic cell module to ensure contact on the photovoltaic cell module.

13. The method according to claim 11, wherein accommodating the photovoltaic cell module in the rear housing comprises; applying a volume adhesive in a recess in the rear housing; positioning the photovoltaic cell module in the recess in a way that the upper surface of the photovoltaic cell module is flush with an upper surface of the rear housing; and hardening the volume adhesive.

14. The method according to claim 11, wherein an additional housing comprising a conductive layer is provided encompassing the rear housing as well as contacting a complete edge area of the grid.
